(19) United States
(12) Patent Application Publication
(10) Pub. No.: US 2026/0068346 A1
(43) Pub. Date: Mar. 5, 2026

(54) IMAGE SENSING DEVICE

(71) Applicant: SK hynix Inc., Icheon-si (KR)

(72) Inventor: Gon Ji LEE, Icheon-si (KR)

(21) Appl. No.: 19/053,324

(22) Filed: Feb. 13, 2025

(30) Foreign Application Priority Data
Sep. 3, 2024 (KR) 10-2024-0119380

(51) Int. Cl. H10F 39/00; H10F 39/18

(52) U.S. Cl. CPC H10F 39/811; H10F 39/182; H10F 39/809

(57) ABSTRACT

Image sensing devices are disclosed. In an embodiment, an image sensing device can exhibit strong resistance to electromigration (EM) by inserting an additional conductive layer having high resistance to electromigration (EM) into conductive layers of an electrode pad. The image sensing device including such an electrode pad can withstand chemical treatment and other treatments required during the analysis of a semiconductor chip in which the image sensing device is implemented.

### CROSS-REFERENCE TO RELATED APPLICATION

This patent document claims the priority and benefits of Korean patent application No. 10-2024-0119380, filed on Sep. 3, 2024, the disclosure of which is incorporated herein by reference in its entirety as part of the disclosure of this patent document.

### TECHNICAL FIELD

The technology and embodiments disclosed in this patent document generally relate to an image sensing device, and more particularly to an image sensing device provided with an electrode pad having a stacked structure.

### BACKGROUND

An image sensing device captures optical images by converting light into electrical signals using a photosensitive semiconductor material. With advancements in automotive, medical, computer and communication industries, the demand for high-performance image sensing devices has grown across various fields such as smartphones, digital cameras, game machines, IoT (Internet of Things), robots, security cameras and medical micro cameras.

The image sensing device may be broadly classified into charge coupled device (CCD) image sensing devices and complementary metal oxide semiconductor (CMOS) image sensing devices. CCD image sensing devices offer superior image quality, but typically consume more power and are larger compared to CMOS image sensing devices.

CMOS image sensing devices are smaller and consume less power than CCD image sensing devices. Additionally, they are fabricated using CMOS fabrication technology, allowing photosensitive elements and signal processing circuitry can be integrated into a single chip. This enables the production of miniaturized, cost-effective image sensing devices. As a result, CMOS image sensing devices are increasingly used in applications such as mobile devices.

### SUMMARY

Various embodiments of the disclosed technology relate to an image sensing device having a new pad structure. The pad structure can prevent defects such as voids caused by electromigration (EM) from occurring, and can provide a structure that is resistant to corrosion.

In an embodiment of the disclosed technology, an image sensing device may include: a pixel area configured to generate an electrical signal in response to incident light; and a pad area arranged outside the pixel area, and including an electrode pad that includes a first conductive layer with a first susceptibility to electromigration and a second conductive layer with a second susceptibility to electromigration. The first conductive layer may be arranged over the second conductive layer, and the second susceptibility of the second conductive layer may be lower that the first susceptibility of the first conductive layer.

In some implementations, the pad area may further include a pad open area contacting a center portion of the first conductive layer. The pad area may further include a capping layer arranged over an edge portion of the first conductive layer.

In some implementations, the capping layer may include at least one of tantalum, tantalum silicide, titanium, or titanium silicide.

In some implementations, the second conductive layer may have a higher melting point or higher boiling point than the first conductive layer.

In some implementations, the second conductive layer may have a higher resistivity than the first conductive layer.

In some implementations, the second conductive layer may have a higher Young's modulus than the first conductive layer.

In some implementations, the second conductive layer may have a lower self-diffusion coefficient than the first conductive layer.

In some implementations, the electrode pad may further include: a third conductive layer arranged below the second conductive layer; an upper capping layer arranged over the first conductive layer; and a lower capping layer further arranged below the third conductive layer.

In some implementations, each of the upper capping layer and the lower capping layer may include at least one of tantalum, tantalum silicide, titanium, or titanium silicide. Each of the first conductive layer and the third conductive layer may include at least one of aluminum (Al) and copper (Cu). The second conductive layer may include tungsten (W).

In another embodiment of the disclosed technology, an image sensing device may include: a pixel substrate configured to include a first surface upon which light is incident and a second surface facing away or opposite to the first surface; a logic substrate configured to include a third surface contacting the second surface and an electrode pad arranged under the third surface; and a pad trench extending in one direction from the first surface to penetrate the pixel substrate, and further extending from the third surface into the interior of the logic substrate to contact the electrode pad. The electrode pad may include a first conductive layer and at least one second conductive layer arranged under the first conductive layer. The second conductive layer may exhibit a lower susceptibility to electromigration (EM) compared to the first conductive layer.

In some implementations, the first conductive layer may include a surface where the electrode pad contacts the pad trench, the surface being located at a center portion of the first conductive layer. A capping layer may be arranged over an edge portion of the first conductive layer.

In some implementations, the capping layer may include at least one of tantalum, tantalum silicide, titanium, or titanium silicide.

In some implementations, the second conductive layer may have a higher melting point than the first conductive layer.

In some implementations, the second conductive layer may have a higher resistivity than the first conductive layer.

In some implementations, the second conductive layer may have a higher Young's modulus than the first conductive layer.

In some implementations, the second conductive layer may have a lower self-diffusion coefficient than the first conductive layer.

In some implementations, the electrode pad may further include: a third conductive layer arranged below the second conductive layer; an upper capping layer arranged over the first conductive layer; and a lower capping layer further arranged below the third conductive layer.

In some implementations, each of the upper capping layer and the lower capping layer may include at least one of tantalum, tantalum silicide, titanium, and titanium silicide. Each of the first conductive layer and the third conductive layer may include at least one of aluminum (Al) or copper (Cu). The second conductive layer may include tungsten (W).

In another embodiment of the disclosed technology, an image sensing device may include: a pixel area configured to generate an electrical signal in response to incident light; and a pad area arranged outside the pixel area, and including an electrode pad that includes a first conductive layer with a first electromigration (EM) index and a second conductive layer with a second EM index. The first conductive layer may be arranged over the second conductive layer. The second conductive layer may have a lower electromigration (EM) index than the first conductive layer. The first and second indices indicate susceptibility to electromigration (EM).

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram schematically illustrating an example of an image sensing device based on some embodiments of the disclosed technology.

FIG. 2 is a perspective view schematically illustrating an example structure of the image sensing device based on some embodiments of the disclosed technology.

FIG. 3 is a plan view schematically illustrating an example structure of a pixel substrate for use in the image sensing device of FIG. 2 based on some embodiments of the disclosed technology.

FIG. 4 is a cross-sectional view schematically illustrating a cross-section of the pixel substrate taken along the line X-X′ of FIG. 3 based on some embodiments of the disclosed technology.

FIG. 5 is an enlarged view illustrating a region (Y) of FIG. 4 based on some embodiments of the disclosed technology.

### DETAILED DESCRIPTION

This patent document provides embodiments and examples of an image sensing device that includes an electrode pad with a stacked structure. In some embodiments, the image sensing device is implemented to substantially address one or more technical or engineering issues and mitigate limitations or disadvantages encountered in some image sensing devices. Some embodiments of the disclosed technology relate to an image sensing device having a new pad structure that can minimize defects such as voids caused by electromigration (EM) and enhance resistance to corrosion. In recognition of the issues above, in some embodiments of the disclosed technology, an image sensing device may include a pad structure that can minimize the occurrence of electromigration (EM)-induced defects, such as corrosion, during chemical treatment processes involved in an analysis process of the image sensing device. In some embodiments of the disclosed technology, an image sensing device may include a pad structure offering higher thermal stability. In some embodiments of the disclosed technology, an image sensing device improve thermal stability and/or resistance to electromigration (EM), ensuring that an electrode pad remains undamaged during the analysis of a substrate structure embedded in the image sensing device.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

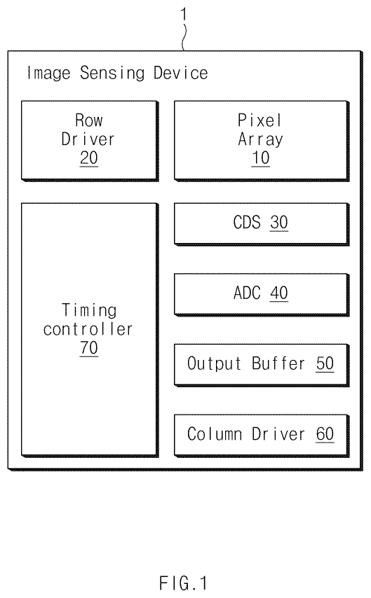

FIG. 1 is a block diagram schematically illustrating an example of an image sensing device 1 based on some embodiments of the disclosed technology.

The image sensing device 1 may include a pixel array 10, a row driver 20, a correlated double sampler (CDS) 30, an analog-to-digital converter (ADC) 40, an output buffer 50, a column driver 60, and a timing controller 70. The components of the image sensing device 1 illustrated in FIG. 1 are discussed by way of example only, and this patent document encompasses numerous other changes, substitutions, variations, alterations, and modifications. In some embodiments discussed in this patent document, the word “pixel” can be used to indicate an image sensing pixel that is structured to detect incident light to generate electrical signals carrying images in the incident light.

The pixel array 10 may include a plurality of unit pixels arranged in rows and columns. In one example, the plurality of unit pixels can be arranged in a two-dimensional (2D) pixel array including rows and columns. In another example, the plurality of unit pixels can be arranged in a three-dimensional (3D) pixel array. The plurality of unit pixels may convert an optical signal into an electrical signal on a unit pixel basis or a pixel group basis, where pixels in a pixel group share at least certain internal circuitry. A plurality of unit pixels may convert incident light into an electrical signal. Each of the unit pixels may generate an image signal acting as an electrical signal corresponding to a target object to be captured. A plurality of unit pixels may convert incident light to generate an electrical signal, and may generate an image signal corresponding to the captured object as an electrical signal.

The pixel array 10 may receive driving signals (for example, a row selection signal, a reset signal, a transmission (or transfer) signal, etc.) from the row driver 20. Upon receiving the driving signal, the unit pixels may be activated to perform the operations corresponding to the row selection signal, the reset signal, and the transfer signal.

The row driver 20 may activate the pixel array 10 to perform certain operations on the unit pixels in the corresponding row based on control signals provided by controller circuitry such as the timing controller 70. In some implementations, the row driver 20 may select one or more pixel groups arranged in one or more rows of the pixel array 10. The row driver 20 may generate a row selection signal to select one or more rows from among the plurality of rows. The row driver 20 may sequentially enable the reset signal and the transfer signal for the unit pixels arranged in the selected row. The pixel signals generated by the unit pixels arranged in the selected row may be output to the correlated double sampler (CDS) 30.

The correlated double sampler (CDS) 30 may remove undesired offset values of the unit pixels using correlated double sampling. In one example, the correlated double sampler (CDS) 30 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 30 may obtain a pixel signal generated only by the incident light without causing noise. In some implementations, upon receiving a clock signal from the timing controller 70, the CDS 30 may sequentially sample and hold voltage levels of the reference signal and the pixel signal, which are provided to each of a plurality of column lines from the pixel array 10. That is, the CDS 30 may sample and hold the voltage levels of the reference signal and the pixel signal which correspond to each of the columns of the pixel array 10. In some implementations, the CDS 30 may transfer the reference signal and the pixel signal of each of the columns as a correlate double sampling (CDS) signal to the ADC 40 based on control signals from the timing controller 70.

The ADC 40 is used to convert analog CDS signals received from the CDS 30 into digital signals. In some implementations, the ADC 40 may be implemented as a ramp-compare type ADC. The analog-to-digital converter (ADC) 40 may compare a ramp signal received from the timing controller 70 with the CDS signal received from the CDS 30, and may thus output a comparison signal indicating the result of comparison between the ramp signal and the CDS signal. The analog-to-digital converter (ADC) 40 may count a level transition time of the comparison signal in response to the ramp signal received from the timing controller 70, and may output a count value indicating the counted level transition time to the output buffer 50.

The output buffer 50 may temporarily store column-based image data provided from the ADC 40 based on control signals of the timing controller 70. The image data received from the ADC 40 may be temporarily stored in the output buffer 50 based on control signals of the timing controller 70. The output buffer 50 may provide an interface to compensate for data rate differences or transmission rate differences between the image sensing device and other devices.

The column driver 60 may select a column of the output buffer 50 upon receiving a control signal from the timing controller 70, and sequentially output the image data, which are temporarily stored in the selected column of the output buffer 50. In some implementations, upon receiving an address signal from the timing controller 70, the column driver 60 may generate a column selection signal based on the address signal, may select a column of the output buffer 50 using the column selection signal, and may control the image data received from the selected column of the output buffer 50 to be output as an output signal.

The timing controller 70 may generate signals for controlling operations of the row driver 20, the ADC 40, the output buffer 50 and the column driver 60. The timing controller 70 may provide the row driver 20, the column driver 60, the ADC 40, and the output buffer 50 with a clock signal required for the operations of the respective components of the image sensing device, a control signal for timing control, and address signals for selecting a row or column. In some implementations, the timing controller 70 may include a logic control circuit, a phase lock loop (PLL) circuit, a timing control circuit, a communication interface circuit and others.

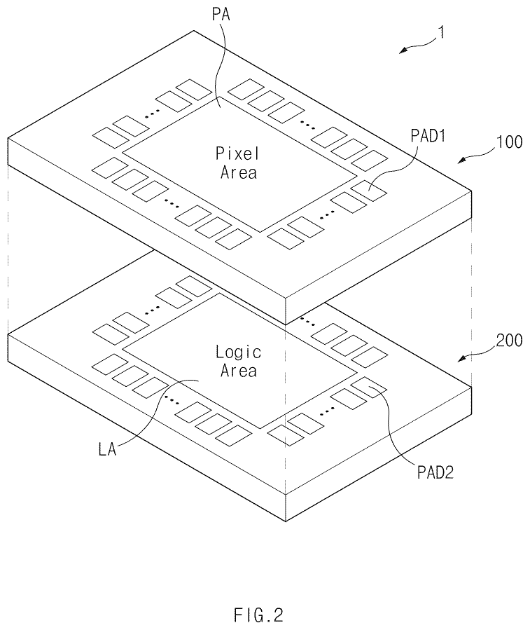

FIG. 2 is a perspective view schematically illustrating an example structure of the image sensing device 1 based on some embodiments of the disclosed technology.

Referring to FIG. 2, the image sensing device 1 may include a pixel substrate 100 and a logic substrate 200.

The pixel substrate 100 may be disposed on the logic substrate 200. The pixel substrate 100 may include: a pixel area (PA) in which the pixel array 10 illustrated in FIG. 1 is arranged; and a first pad area (PAD1) located outside the pixel area (PA).

The logic substrate 200 may include: a logic area (LA) in which the row driver 20, the CDS 30, the ADC 40, the output buffer 50, the column driver 60, and the timing controller 70 illustrated in FIG. 1 are formed; and a second pad area (PAD2) that is located outside the logic area (LA) and overlaps the first pad area (PAD1).

The pixel substrate 100 and the logic substrate 200 may be bonded together using a bonding technique, such as hybrid bonding.

The logic area (LA) may be arranged in a center portion of the logic substrate 200. The logic area (LA) may overlap the pixel area (PA) arranged in the pixel substrate 100 in the vertical direction of the logic substrate 200. The logic area (LA) may include electronic components (e.g., transistors) that generate control signals for controlling the operation of the unit pixels (PXs) and generate images by processing pixel signals output from the unit pixels (PXs).

The first pad area (PAD1) and the second pad area (PAD2) may overlap in the vertical direction of the pixel substrate 100 or the logic substrate 200. The first pad area (PAD1) and the second pad area (PAD2) may be included in one pad area.

The above one pad area may include a conductive layer that receives an electrical signal from the outside of the image sensing device 1 or transmits an electrical signal to the outside of the image sensing device 1.

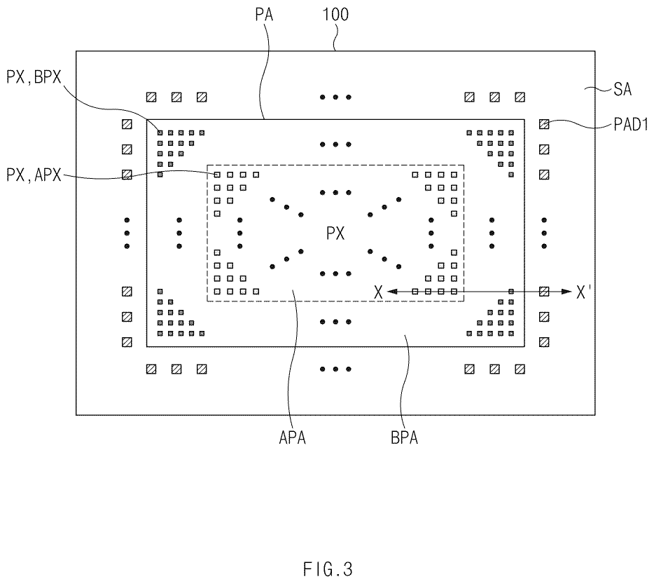

FIG. 3 is a plan view schematically illustrating an example structure of the pixel substrate for use in the image sensing device of FIG. 2 based on some embodiments of the disclosed technology.

Referring to FIG. 3, the pixel substrate 100 may include a pixel area (PA) and a surrounding area (SA).

The pixel area (PA) may be arranged in the center portion of the pixel substrate 100. The pixel area (PA) may include a plurality of unit pixels (PXs) arranged in rows and columns. Each unit pixel (PX) may include a photoelectric conversion element, an optical filter, a microlens, and pixel transistors. The plurality of unit pixels (PX) arranged in the rows may refer to, for example, a plurality of unit pixels (PX) arranged in a horizontal direction as shown in FIG. 3. The plurality of unit pixels (PXs) arranged in the columns may refer to, for example, a plurality of unit pixels (PXs) arranged in a vertical direction as shown in FIG. 3.

The pixel area (PA) may include an active pixel area (APA) and an optical black pixel area (BPA).

The active pixel area (APA) may include a plurality of active unit pixels (APXs) arranged in rows and columns.

Each of the active unit pixels (APXs) may generate an electrical signal in response to light incident upon the substrate area 100. For example, a photoelectric conversion element in each active unit pixel (APX) may generate photocharges in response to the incident light, and the generated photocharges may be converted into a pixel signal (or an electrical signal) and output by the pixel transistors. The pixel transistors may include, for example, at least one of a transfer transistor, a reset transistor, a source follower transistor, or a selection transistor.

The transfer transistor may transfer the photocharges generated by the photoelectric conversion element to a floating diffusion region. The source follower transistor may output a pixel signal corresponding to the voltage level of the floating diffusion region. The selection transistor may act as a switch for determining which active unit pixel of a plurality of active unit pixels (APXs) will be used to output the pixel signal. The reset transistor may reset the voltage level of the floating diffusion region to a reference voltage level.

The optical black pixel area (BPA) may include a plurality of optical black unit pixels (BPX) formed outside the active pixel area (APA) and arranged along the horizontal or vertical extension lines of the active pixel area (APA). The optical black pixel area (BPA) may be located on one side of the active pixel area (APA), on both sides of the active pixel area (APA), or surround three or four sides of the active pixel area (APA). As shown in FIG. 3, in an embodiment, the optical black pixel area (BPA) may surround four sides of the active pixel area (APA).

The optical black unit pixels (BPX) may include a light blocking structure configured to block light incident upon the substrate area 100. The optical black unit pixel (BPX) with the light blocking structure may output a signal for correcting a pixel signal output from the active unit pixel (APX).

The surrounding area (SA) may be an edge area of the pixel substrate 100 that surrounds the pixel area (PA). The surrounding area (SA) may include a plurality of first pad areas (PAD1).

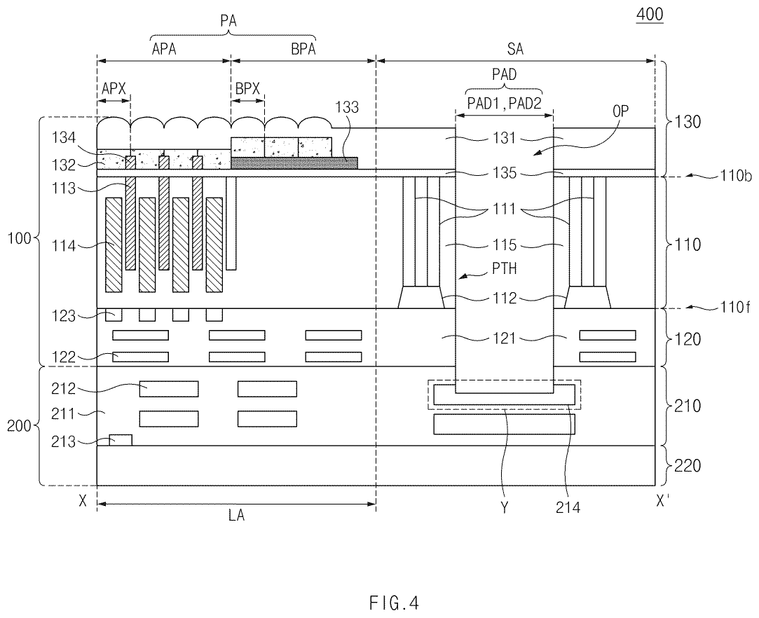

FIG. 4 is a cross-sectional view schematically illustrating a cross-section of the pixel substrate taken along the line X-X′ of FIG. 3 based on some embodiments of the disclosed technology.

In FIG. 4, in some embodiments, components with the same shape or pattern may be considered identical components. Referring to FIG. 4, a cross-section structure 400 of the substrate taken along the line X-X′ of FIG. 3 may include a pixel substrate 100, a logic substrate 200, and a pad area (PAD).

The pixel substrate 100 may include a semiconductor layer 110, a pixel interconnect layer 120, and a light incident layer 130.

The semiconductor layer 110 may include a deep pad isolation layer 111, a shallow pad isolation layer 112, a pixel isolation layer 113, a photoelectric conversion element 114, and a semiconductor area 115.

The deep pad isolation layer 111 may isolate the pad area (PAD) from other areas. The deep pad isolation layer 111 may be formed, for example, to surround the pad area (PAD) within the semiconductor layer 110. The deep pad isolation layer 111 may have a structure that is recessed from the back surface 110b of the semiconductor layer 110 into the interior of the semiconductor layer 110, but is not limited thereto. For example, the deep pad isolation layer 111 may also be recessed from the front surface 110f into the interior of the semiconductor layer 110. The deep pad isolation layer 111 may refer to a structure that is formed by forming a trench that is recessed into the interior of the semiconductor layer 110 from either the back surface 110b or the front surface 110f, and gap-filling the interior of the trench with an insulation material and/or polysilicon.

The shallow pad isolation layer 112, together with the deep pad isolation layer 111, may electrically isolate the pad area (PAD) from other areas. The shallow pad isolation layer 112 may be formed, for example, to surround the pad area (PAD) within the semiconductor layer 110. The shallow pad isolation layer 112 may have a structure that is recessed from the front surface 110f of the semiconductor layer 110 into the interior of the semiconductor layer 110, but is not limited thereto. For example, the shallow pad isolation layer 112 may also be recessed from the back surface 110b into the interior of the semiconductor layer 110. The shallow pad isolation layer 112 may refer to a structure formed by gap-filling a trench structure (e.g., a trench structure that is recessed from the front surface 110f or the back surface 110b into the interior of the semiconductor layer 110) with an insulation material and/or polysilicon. In addition, the shallow pad isolation layer 112 may be omitted as needed.

The pixel isolation layer 113 may have a structure that is recessed from the back surface 110b of the semiconductor layer 110 into the interior of the semiconductor layer 110, but is not limited thereto. For example, the pixel isolation layer 113 may be recessed from the front surface 110f into the interior of the semiconductor layer 110. The pixel isolation layer 113 may prevent optical crosstalk between adjacent active pixels (APXs).

The photoelectric conversion element 114 may be arranged inside the semiconductor layer 110. At least one photoelectric conversion element 114 may be arranged inside each of the active unit pixels (APXs). The photoelectric conversion element 114 may generate photocharges in response to incident light received from the back surface 110b.

The semiconductor area 115 may refer to a region excluding components that are disposed inside the semiconductor layer 110. The semiconductor area 115 may include, for example, a silicon (Si) material. The semiconductor area 115 may include a region doped with certain impurities.

The pixel interconnect layer 120 may include at least one pixel interconnect insulation layer 121, at least one pixel interconnect metal layer 122, and at least one pixel transistor 123.

The pixel interconnect insulation layer 121 may fill a space between the pixel interconnect metal layers 122 or may surround the pixel interconnect metal layers 122. The pixel interconnect insulation layer 121 may include, for example, an insulation material such as silicon oxide or silicon nitride. The pixel interconnect insulation layer 121 may prevent electrical interaction between the pixel interconnect metal layers 122.

The pixel interconnect metal layer 122 may be electrically connected to a specific component, such as a pixel transistor 123. For example, the pixel interconnect metal layer 122 may be electrically connected to a gate of a transfer transistor, which is one of the pixel transistors 123. When the pixel substrate 100 receives an operating voltage of the transfer transistor through the pixel interconnect metal layer 122, photocharges generated by the photoelectric conversion element 114 may move to a floating diffusion region (not shown).

The pixel transistor 123 may be a gate structure of the transfer transistor described in FIG. 3, but is not limited thereto. For example, the pixel transistor 123 may be a gate structure of one of the reset transistor, the source follower transistor, or the selection transistor. The source and drain regions of the pixel transistor 123 may be arranged in the semiconductor area 115.

The light incident layer 130 may include a microlens layer 131, an optical filter 132, a light blocking structure 133, a grid structure 134, and an anti-reflection layer 135.

The microlens layer 131 may include a convex surface that allows light incident from the outside to be focused onto each unit pixel (APX, BPX). The microlens layer 131 may allow the incident light to be focused onto the photoelectric conversion element 114 of the corresponding unit pixel (APX, BPX). The microlens layer 131 may include a lens material (e.g., a light transmissive photoresist).

The optical filter 132 may be arranged on the back surface 110b within the pixel area (PA). The optical filter 132 may be arranged to correspond to the unit pixels (APX, BPX), and may transmit light having a target wavelength range from among incident lights. The optical filter 132 may filter out light having the remaining wavelengths other than the target wavelength range. The plurality of optical filters 132 may include a red optical filter that transmits red light, a green optical filter that transmits green light, and a blue optical filter that transmits blue light. In an embodiment, the red, green, and blue optical filters may be arranged in a Bayer pattern.

The light blocking structure 133 may be arranged within the optical black pixel area (BPA). The light blocking structure 133 may block light that has passed through the microlens layer 131 and/or the optical filter 132. The light blocking structure 133 may include a material having a high light absorption rate (e.g., tungsten W). The light blocking structure 133 may be arranged over the back surface 110b. The light blocking structure 133 may be arranged over the anti-reflection layer 135.

The grid structure 134 may be arranged between adjacent active unit pixels (APXs). For example, the grid structure 134 may be arranged between adjacent optical filters 132. The grid structure 134 may prevent optical crosstalk between adjacent active unit pixels (APXs). The grid structure 134 may include a material having low light transmittance. The grid structure 134 may include a material having high light reflectivity.

The anti-reflection layer 135 may be arranged over the back surface 110b. The anti-reflection layer 135 may reduce the reflection of light at the back surface 110b after passing through the optical filter 132. The anti-reflection layer 135 may include a material having high light transmittance.

The logic substrate 200 can include a first logic interconnect layer 210 and a second logic interconnect layer 220.

The first logic interconnect layer 210 may include a logic interconnect insulation layer 211, a logic interconnect metal layer 212, a logic transistor 213, and an electrode pad 214.

The logic interconnect insulation layer 211 may include an insulation material disposed between the logic transistor 213 and the logic interconnect metal layer 212. For example, the logic interconnect insulation layer 211 may include at least one of silicon oxide, silicon nitride, and silicon oxide nitride. The logic interconnect insulation layer 211 may prevent electrical interaction between the logic interconnect metal layers 212 that are spaced apart from each other.

The logic interconnect metal layer 212 may electrically connect the logic transistor 213 to the electrode pad 214. In addition, the logic interconnect metal layer 212 may electrically connect the logic transistors 213 within the logic area (LA). The logic interconnect metal layer 212 may be formed in a multilayer structure. The metal wires on the uppermost layer from among the logic interconnect metal layers 212 may be formed thicker than the other metal wires.

The logic transistor 213 may generate control signals for controlling the operation of the unit pixels (PXs), and may process pixel signals output from the unit pixels (PXs) to generate an image. For example, the logic transistor 213 may include transistors that constitute the row driver 20, the CDS 30, the ADC 40, the output buffer 50, the column driver 60, and the timing controller 70 illustrated in FIG. 1.

The electrode pad 214 may be configured to be electrically connected to an external device. For example, the electrode pad 214 may be bonded to a bonding wire, and the bonding wire may electrically connect the electrode pad 214 to the external device.

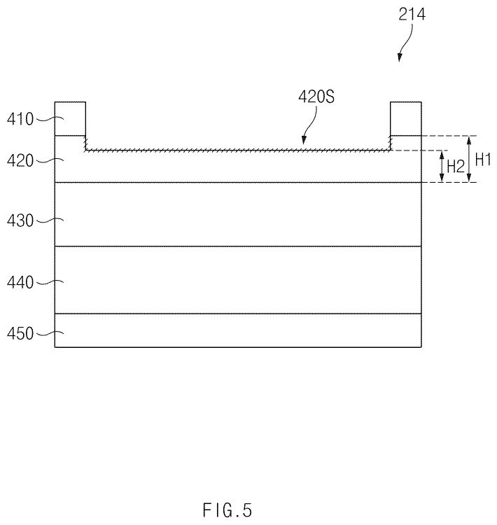

The electrode pad 214 may be arranged in the logic substrate 200. The electrode pad 214 may be arranged in the first logic interconnect layer 210 of the logic substrate 200. The electrode pad 214 may be arranged in the pad area (PAD). A more detailed description of the electrode pad 214 will be given later with reference to FIG. 5.

The second logic interconnect layer 220 may include source/drain regions of the logic transistor 213. Although the second logic interconnect layer 220 is not illustrated in FIG. 4, the second logic interconnect layer 220 may include an additional interconnect layer as needed.

The pad area (PAD) may include a pad open area (OP), a pad trench (PTH), and an electrode pad 214. The pad area (PAD) may include the first pad area (PAD1) and the second pad area (PAD2) of FIG. 2.

The first pad area (PAD1) may correspond to an area penetrating the pixel substrate 100, and the second pad area (PAD2) may correspond to a pad open area (OP) and an electrode pad 214 located in the logic substrate 200, but distinction between the first pad area (PAD1) and the second pad area (PAD2) may not restrict characteristics of the pad area (PAD).

The pad trench (PTH) may be arranged in the pad area (PAD) within the surrounding area (SA). The pad trench (PTH) may extend in one direction from the back surface 110b of the pixel substrate 100 into the interior of the pixel substrate 100, and may penetrate the pixel substrate 100. The pad trench (PTH) may further extend into the interior of the logic substrate 200 in the one direction from the surface where the pixel substrate 100 and the logic substrate 200 contact each other. The bottom surface of the pad trench (PTH) may contact the electrode pad 214. The pad trench (PTH) may extend further into the interior of the logic substrate 200 in the above-described one direction. The pad trench (PTH) may extend further into the interior of the electrode pad 214 so that a conductive layer arranged inside the electrode pad 214 may be exposed to the pad open area (OP).

The pad open area (OP) may provide a space where the electrode pad 214 can directly contact the external bonding wire. The pad open area (OP) may be a space formed by the pad trench (PTH). The pad open area (OP) may refer to an internal space of the pad trench (PTH).

The electrode pad 214 may be electrically connected to the bonding wire, etc. For example, the electrode pad 214 may be configured to receive an electrical signal from the outside or transmit an electrical signal to the outside. A more detailed description of the electrode pad 214 will be given later with reference to FIG. 5.

FIG. 5 is an enlarged view illustrating the Y region of FIG. 4 based on some embodiments of the disclosed technology.

Referring to FIGS. 4 and 5, the Y region may be an electrode pad cross-section 500 for the electrode pad 214 of FIG. 4.

The electrode pad 214 may include an upper capping layer 410, a first conductive layer 420, a second conductive layer 430, a third conductive layer 440, and a lower capping layer 450. The side, lower, and upper edge portions of the electrode pad 214 may be surrounded by the logic interconnect insulation layer 211 (see FIG. 4). The center portion of the upper portion of the electrode pad 214 may contact a region from the pad open area (OP of FIG. 4) to the pad trench (PTH).

The upper capping layer 410 may be arranged in the edge region of the electrode pad 214. The upper capping layer 410 may contact either the pad open area (OP of FIG. 4) contacting the center region of the upper part of the electrode pad 214 or the side portion of the pad trench (PTH). The upper capping layer 410 may include, for example, a material having high adhesion to the logic interconnect insulation layer 211 so that the electrode pad 214 can be well adhered to the first logic interconnect layer 210. The upper capping layer 410 may include, for example, at least one of titanium (Ti), tantalum (Ta), titanium silicide, and tantalum silicide.

The first conductive layer 420 may be arranged under the upper capping layer 410. The first conductive layer 420 may include an electrode pad surface 420S contacting the pad open area (OP). The first conductive layer 420 may have a stepped structure in which a thickness of the edge portion is different from a thickness of the center portion. The stepped structure may be a structure that is formed as the pad trench (PTH) extends to a part of the electrode pad 214. For example, the thickness (H2) of the center portion of the first conductive layer 420 may be smaller than the thickness (H1) of the edge portion of the first conductive layer 420. The first conductive layer 420 may be, for example, a conductive layer through which a voltage is applied to the electrode pad 214 from the outside by the bonding wire described in FIG. 4. As the first conductive layer 420 has the stepped structure, the first conductive layer 420 may be reliably brought into contact with the pad open area (OP). Through the stepped structure, an electrode pad surface 420S on which the bonding wire can be bonded to the first conductive layer 420 may be secured.

The third conductive layer 440 may be arranged below the second conductive layer 430. The third conductive layer 440 may be arranged over the lower capping layer 450. Each of the first conductive layer 420 and the third conductive layer 430 may include a metal having high electrical conductivity, such as aluminum (Al), copper (Cu), etc.

The second conductive layer 430 may be arranged between the first conductive layer 420 and the third conductive layer 440. The second conductive layer 430 may include a material that exhibits high resistance to electromigration (EM). In one example, the second conductive layer 430 may include a material that exhibits a low susceptibility to electromigration (EM). The second conductive layer 430 may include a material that exhibits a relatively lower probability of electromigration (EM) occurrence as compared to the first conductive layer 420 and the third conductive layer 440. Here, the lower probability of electromigration (EM) occurrence may mean, for example, that a mean-time to failure (MTTF) (e.g., a time until failure) due to electromigration (EM) under the same conditions is longer.

In some embodiment, an EM index is a parameter that numerically represents the likelihood or tendency that electromigration (EM) will occur. In some embodiment, the EM index can serve as a parameter to test whether a material is prone to electromigration (EM), with higher values indicating greater susceptibility to electromigration (EM). In other words, a lower EM index indicates that electromigration (EM) is less likely to occur (e.g., there may be stronger resistance to electromigration (EM)).

Electromigration (EM) may refer to a phenomenon in which atoms may move due to physical forces resulting from collisions between electrons and atoms (or atomic nuclei) when an electric current flows in a material. In other words, the likelihood of electromigration (EM) tends to decrease (e.g., the EM index tends to decrease) when atoms in the material are less prone to movement.

For example, the EM index may decrease as the melting or boiling point of a material increases. Similarly, the EM index may decrease as the Young's modulus of a material increases. Additionally, materials with higher resistivity may exhibit a lower EM index. Furthermore, a higher degree of crystallinity in a material may correspond to a lower EM index. Lastly, materials with a lower self-diffusion coefficient may exhibit a lower EM index. Factors that can affect the above EM index are not limited to the melting point (or boiling point), Young's modulus, resistivity, degree of crystallinity, and self-diffusion coefficient mentioned above. For example, materials with a higher atomic weight may exhibit a lower EM index as heavier atoms are more resistance to movement caused by physical force resulting from collisions with electrons.

The second conductive layer 430 may have a lower EM index than the first conductive layer 420 or the third conductive layer 440.

For example, the second conductive layer 430 may have a higher melting point than the first conductive layer 420 or the third conductive layer 440. The second conductive layer 430 may have a higher Young's modulus than the first conductive layer 420 or the third conductive layer 440. The second conductive layer 430 may have a higher resistivity than the first conductive layer 420 or the third conductive layer 440. The second conductive layer 430 may have a higher degree of crystallinity than the first conductive layer 420 or the third conductive layer 440. The second conductive layer 430 may have a lower self-diffusion coefficient than the first conductive layer 420 or the third conductive layer 440. The second conductive layer 430 may include a material having a higher atomic weight than the first conductive layer 420 or the third conductive layer 440.

As the second conductive layer 430 is arranged below the first conductive layer 420 or as the second conductive layer 430 is arranged between the first conductive layer 420 and the third conductive layer 440, thermal stability of the electrode pad 214 can be improved and electromigration (EM) can be reduced.

The second conductive layer 430 may compensate for the high susceptibility of the first conductive layer 420 or the third conductive layer 440 to electromigration (EM).

Although FIG. 5 illustrates a stacked structure of the first to third conductive layers (420, 430, 440) as an example, the scope of the embodiments of the disclosed technology is not limited thereto. For example, the conductive layer having a low EM index may be further inserted between the third conductive layers 440.

In an embodiment, the second conductive layer 430 may include, between the first conductive layer 420 including aluminum and the third conductive layer 440 including aluminum, a material (e.g., tungsten W) having relatively higher resistance to EM compared to aluminum, thereby reducing the occurrence of voids, hillocks, or corrosion in the first conductive layer 420.

In this way, the electrode pad 214 based on some embodiments can improve its thermal stability, defects in the electrode pad 214 can be prevented or reduced even at high temperatures during analysis of the pixel substrate 100 or the logic substrate 200 included in the image sensing device 1.

In addition, the electrode pad 214 based on some embodiments can reduce the degree of EM occurring during a chemical treatment by improving its resistance to electromigration (EM), even when the chemical treatment is required during analysis of the pixel substrate 100 or the logic substrate 200.

In the case where the electrode pad 214 includes a single conductive layer that includes a metal (e.g., aluminum Al or copper Cu) having high electrical conductivity without the second conductive layer 430 that includes a material having high resistance to EM, there is a possibility that the single conductive layer formed inside the electrode pad 214 may corrode and be completely lost during the chemical treatment. However, by incorporating the second conductive layer 430 within the electrode pad 214, it is possible to reduce or prevent corrosion or loss of the conductive layer including the metal with high electrical conductivity, thereby facilitating the analysis of electrical characteristics.

In addition, since the second conductive layer 430 is disposed in the image sensing device 1, damage to the electrode pad 214 may be prevented or reduced when the pixel substrate 100 or the logic substrate 200 embedded in the image sensing device 1 is analyzed.

As discussed above, an image sensing device based on some embodiments may include a pad structure designed to minimize the likelihood of electromigration (EM), which can lead to defects such as corrosion during chemical treatments used in an analysis process of the image sensing device.

In addition, an image sensing device based on some embodiments may include a pad structure having higher thermal stability.

Furthermore, an image sensing device based on some embodiments may exhibit higher thermal stability and/or higher resistance to electromigration (EM), thereby reducing or preventing damage to an electrode pad when analyzing a substrate structure embedded in the image sensing device.

The embodiments of the disclosed technology may offer a variety of effects that can be directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a pixel area configured to generate an electrical signal in response to incident light; and
a pad area arranged outside the pixel area and including an electrode pad that includes a first conductive layer with a first susceptibility to electromigration and a second conductive layer with a second susceptibility to electromigration, wherein the first conductive layer is arranged over the second conductive layer,
wherein the second susceptibility of the second conductive layer is lower that the first susceptibility of the first conductive layer.

2. The image sensing device according to claim 1, wherein the pad area further includes:
a pad open area contacting a center portion of the first conductive layer; and
a capping layer arranged over an edge portion of the first conductive layer.

3. The image sensing device according to claim 2, wherein:
the capping layer includes at least one of tantalum, tantalum silicide, titanium, or titanium silicide.

4. The image sensing device according to claim 1, wherein:
the second conductive layer has a higher melting point or boiling point than the first conductive layer.

5. The image sensing device according to claim 1, wherein:
the second conductive layer has a higher resistivity than the first conductive layer.

6. The image sensing device according to claim 1, wherein:
the second conductive layer has a higher Young's modulus than the first conductive layer.

7. The image sensing device according to claim 1, wherein:
the second conductive layer has a lower self-diffusion coefficient than the first conductive layer.

8. The image sensing device according to claim 1, wherein the electrode pad further includes:
a third conductive layer arranged below the second conductive layer;
an upper capping layer arranged over the first conductive layer; and
a lower capping layer arranged below the third conductive layer.

9. The image sensing device according to claim 8, wherein:
each of the upper capping layer and the lower capping layer includes at least one of tantalum, tantalum silicide, titanium, or titanium silicide;
each of the first conductive layer and the third conductive layer includes at least one of aluminum (Al) or copper (Cu); and
the second conductive layer includes tungsten (W).

10. An image sensing device comprising:
a pixel substrate configured to include a first surface upon which light is incident and a second surface facing away or opposite to the first surface;
a logic substrate configured to include a third surface contacting the second surface and an electrode pad arranged under the third surface; and
a pad trench extending in one direction from the first surface to penetrate the pixel substrate, and further extending from the third surface into an interior of the logic substrate to contact the electrode pad,
wherein the electrode pad includes a first conductive layer and at least one second conductive layer arranged under the first conductive layer,
wherein the second conductive layer exhibits a lower susceptibility to electromigration (EM) compared to the first conductive layer.

11. The image sensing device according to claim 10, wherein:
the first conductive layer includes a surface where the electrode pad contacts the pad trench, the surface being located at a center portion of the first conductive layer; and
a capping layer is arranged over an edge portion of the first conductive layer.

12. The image sensing device according to claim 11, wherein:
the capping layer includes at least one of tantalum, tantalum silicide, titanium, or titanium silicide.

13. The image sensing device according to claim 10, wherein:
the second conductive layer has a higher melting point than the first conductive layer.

14. The image sensing device according to claim 10, wherein:
the second conductive layer has a higher resistivity than the first conductive layer.

15. The image sensing device according to claim 10, wherein:
the second conductive layer has a higher Young's modulus than the first conductive layer.

16. The image sensing device according to claim 10, wherein:
the second conductive layer has a lower self-diffusion coefficient than the first conductive layer.

17. The image sensing device according to claim 10, wherein the electrode pad further includes:
a third conductive layer arranged below the second conductive layer;
an upper capping layer arranged over the first conductive layer; and
a lower capping layer arranged below the third conductive layer.

18. The image sensing device according to claim 17, wherein:
each of the upper capping layer and the lower capping layer includes at least one of tantalum, tantalum silicide, titanium, or titanium silicide;
each of the first conductive layer and the third conductive layer includes at least one of aluminum (Al) or copper (Cu); and
the second conductive layer includes tungsten (W).

19. An image sensing device comprising:
a pixel area configured to generate an electrical signal in response to incident light; and
a pad area arranged outside the pixel area and including an electrode pad that includes a first conductive layer with a first electromigration (EM) index and a second conductive layer with a second EM index,
wherein the first conductive layer is arranged over the second conductive layer;
the second conductive layer has a lower electromigration (EM) index than the first conductive layer; and
the first and second EM indices indicate susceptibility to electromigration (EM).
